(19) United States
(12) Patent Application Publication
(10) Pub. No.: US 2026/0168102 A1
(43) Pub. Date: Jun. 18, 2026

(54) HYDROGEN ADDITION TO LOW-K DIELECTRIC BARRIER FILMS

(71) Applicant: Applied Materials, Inc., Santa Clara, CA (US)

(72) Inventors: Kent Zhao, Santa Clara, CA (US); Albert Kim, Santa Clara, CA (US); Bo Xie, San Jose, CA (US); Chi-I Lang, Cupertino, CA (US); Li-Qun Xia, Cupertino, CA (US)

(73) Assignee: Applied Materials, Inc., Santa Clara, CA (US)

(21) Appl. No.: 18/980,063

(22) Filed: Dec. 13, 2024

(51) Int. Cl. C23C 16/56; C23C 16/36; C23C 16/52

(52) U.S. Cl. CPC C23C 16/56; C23C 16/36; C23C 16/52

(57) ABSTRACT

A method of forming a low-k dielectric layer with barrier properties is disclosed. The method includes forming a dielectric layer by plasma enhanced chemical vapor deposition (PECVD) with the addition of hydrogen (H₂) gas during the process. The addition of hydrogen (H₂) during the PECVD process provides a low-k barrier layer with increased density.

### TECHNICAL FIELD

Embodiments of the present disclosure generally relate to methods of forming barrier layers with low dielectric constants. More particularly, the present disclosure provides methods of forming dense barrier layers having low dielectric constants.

### BACKGROUND

Integrated circuits have evolved into complex devices that can include millions of transistors, capacitors, and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced, it is necessary to use low resistivity conductive materials as well as low dielectric constant insulating materials to obtain suitable electrical performance from such components.

Deposition of films on a substrate surface is an important process in a variety of industries including semiconductor processing, semiconductor manufacturing equipment, diffusion barrier coatings, and dielectrics for magnetic read/write heads. In the semiconductor industry, as an example, miniaturization requires atomic level control of thin film deposition to produce conformal coatings on high aspect structures.

Preventing the movement of elements from one material in an electronic device into another material has been a long recognized problem in the semiconductor art. Diffusion barriers have been developed to prevent the diffusion of large atoms, like metals.

Low-k silicon-based dielectric films are important for the microelectronics manufacturing. Increasing the density of a barrier film may improve oxygen diffusion resistance. Higher density barrier films may prevent oxidation of metal gates in middle-end-of-line (MEOL) applications. Therefore, there is a need in the art for barrier layers having higher densities.

### SUMMARY

One or more embodiments of the disclosure are directed to a method for depositing a film. In one or more embodiments, the method comprises: forming a barrier layer on a substrate surface by exposing the substrate surface to hydrogen (H₂) and a silicon-containing precursor; exposing the substrate to a reactant to react with the silicon-containing precursor to form one or more of a silicon carbonitride (SiCN) film or a silicon oxycarbonitride (SiOCN) film on the substrate; and exposing the substrate surface to a plasma.

Additional embodiments of the disclosure are directed to non-transitory computer readable medium including instructions, that, when executed by a controller of a processing chamber, causes the processing chamber to perform operations of: expose a substrate surface to hydrogen (H₂) and a silicon-containing precursor having a structure of general formula (I) or general formula (II) or a general formula (III) or a general formula (IV)

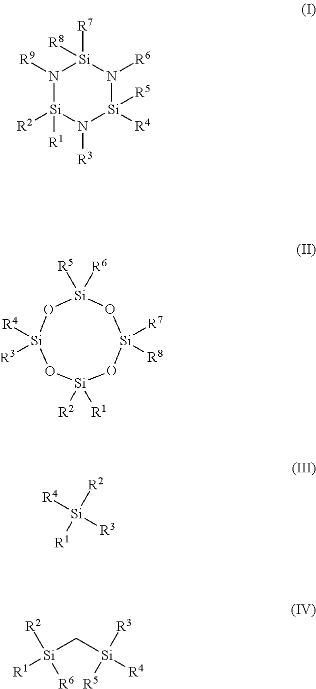

wherein R¹, R², R³, R⁴, R⁵, R⁶, R⁷, R⁸, and R⁹, are independently selected from hydrogen (H), substituted or unsubstituted alkyl, substituted or unsubstituted alkoxy, substituted or unsubstituted vinyl, silane, substituted or unsubstituted amine, or halide; expose the substrate to a reactant to react with the silicon-containing precursor to form one or more of a silicon carbonitride (SiCN) film or a silicon oxycarbonitride (SiOCN) film on the substrate; and expose the substrate surface to a plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a process flow diagram of a method of forming a barrier layer according to one or more embodiments of the disclosure;

FIG. 2 illustrates an exemplary semiconductor device according to one or more embodiments of the disclosure; and

FIG. 3 illustrates a cluster tool according to one or more embodiment of the disclosure.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may include deviations in shapes that result, for example, from manufacturing.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface. In one or more embodiments, the precursor is a silicon based precursor.

One or more embodiments advantageously provide the formation of dense, high-quality, stable dielectric layers through the use of a plasma enhanced chemical vapor deposition (PECVD) process. Additionally, the plasma enhanced CVD process of one or more embodiments forms dense, high-quality, conformal layers of a silicon-containing film, that have low leakage and improved dielectric performance.

Some embodiments of the present disclosure relate to methods for forming a low-k dielectric layer which acts as barrier layer. Some methods of this disclosure advantageously provide methods to provide a dense barrier layer by incorporating hydrogen (H₂) into the process. Some methods of this disclosure advantageously provide methods which provide low-k dielectric barrier layers for use as interlayer dielectrics with high hardness and stiffness.

Embodiments described herein will be described below in reference to a PECVD process that can be carried out using any suitable film deposition system. Any deposition system that is capable of performing PECVD processes may be adapted to benefit from the embodiments described herein. In addition, any system enabling the PECVD processes described herein can be used to advantage. The apparatus description described herein is illustrative and should not be construed or interpreted as limiting the scope of the disclosure.

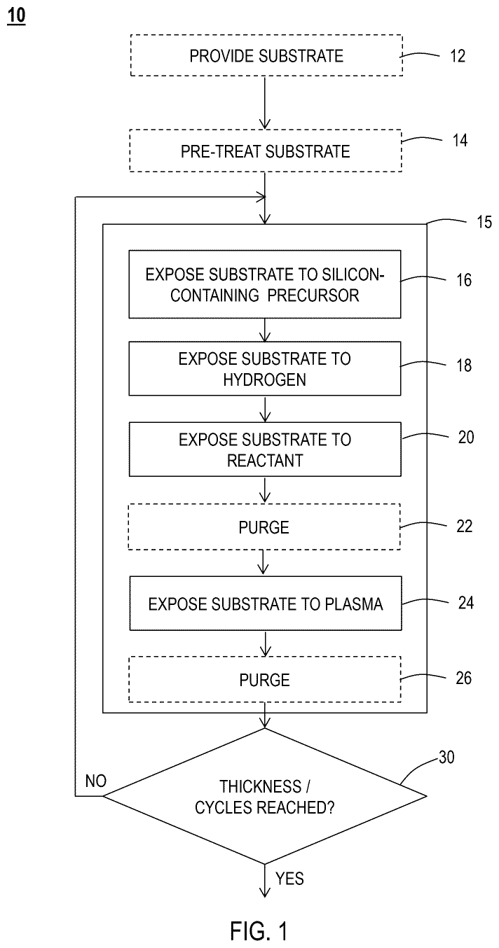

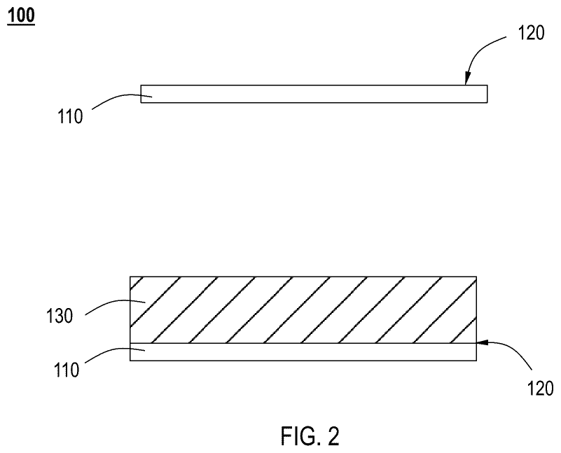

Referring to FIGS. 1 and 2, in some embodiments, the method 10 of forming a low-k dielectric barrier layer 130 begins at operation 12 where a substrate 110 is provided. As used in this specification and the appended claims, the term “provided” means that the substrate 110 is made available for processing (e.g., positioned in a processing chamber).

In some embodiments, the method 10 includes a pre-treatment operation 14. The pre-treatment can be any suitable pre-treatment known to the skilled artisan. Suitable pre-treatments include, but are not limited to, pre-heating, cleaning, soaking, native oxide removal, or deposition of a layer (e.g., titanium nitride (TiN)).

At deposition operation 15, a process is performed to deposit a low-k dielectric barrier layer 130 on the substrate 110 (or substrate surface 120). The deposition process can include one or more operations to form a film on the substrate. In operation 16, the substrate (or substrate surface) is exposed to a silicon-containing precursor to deposit a film 130 on the substrate (or substrate surface). In one or more embodiments, the substrate (or substrate surface) is exposed to a precursor mixture comprising a silicon-containing precursor of general formula (I) or general formula (II).

In one or more embodiments, provided is a process for forming low-k dielectric barrier layer 130, e.g., silicon carbonitride (SiCN) films, using silane precursors, silylmethane precursors, organosilizane precursors, and organosiloxane precursors. In one or more embodiments, the precursor has a structure corresponding to general formula (I) or general formula (II) or general formula (III) or general formula (IV):

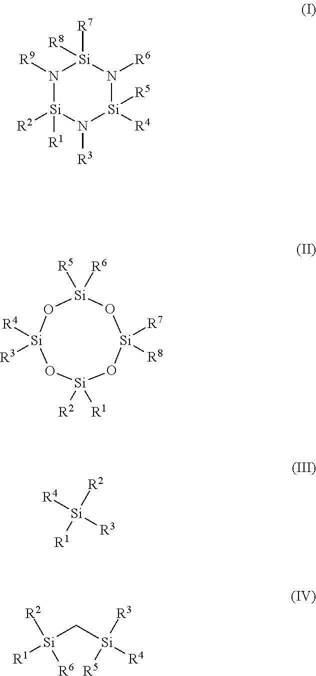

wherein R¹, R², R³, R⁴, R⁵, R⁶, R⁷, R⁸, and R⁹, are independently selected from hydrogen (H), substituted or unsubstituted alkyl, substituted or unsubstituted alkoxy, substituted or unsubstituted vinyl, silane, substituted or unsubstituted amine, or halide.

Unless otherwise indicated, the term “lower alkyl,” “alkyl,” or “alk” as used herein alone or as part of another group includes both straight and branched chain hydrocarbons, containing 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents.

As used herein, the term “alkoxy” includes any of the above alkyl groups linked to an oxygen atom.

As used herein, the terms “vinyl” or “vinyl-containing” refer to groups containing the vinyl group (—CH═CH₂).

As used herein, the term “amine” relates to any organic compound containing at least one basic nitrogen atom, e.g., NR′₂, wherein R′ is independently selected from hydrogen (H) or alkyl.

As used herein, the term “silane” refers to a compound SiR′₃, wherein R′ is independently selected from hydrogen (H) or alkyl.

As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—).

In one or more embodiments, the silicon-containing precursor comprises one or more of silane, disilane, trisilane, tetrasilane, siloxane, octamethylcyclotetrasiloxane, hexamethylcyclotrisilazane, dimethyldimethoxysilane, vinylmethyldimethoxysilane, trimethyl silane (TMS), tetramethyl silane, methoxy(dimethyl)silylmethane, methyl(dimethoxy)silylmethane, bis(trimethylsilyl)methane, nonamethylcyclotrisilazane, hexaethylcyclotrisilazane, octaethylcyclotrisilazane, 2-ethyl-2,4,4,6,6-pentamethyl-1,3,5,2,4,6-triazatrisilinane, hexapropylcyclotrisilazane, octapropylcyclotrisilazane, Di(butan-2-yl)-fluoro-(2,2,4,4,6,6-hexamethyl-1,3,5,2,4,6-triazatrisilinan-1-yl)silane, Tetraethyl-dimethyl-triazatrisilinane, diethyl-tetramethyl-triazatrisilinane, hexapropyltriazatrisilinane, hexamethyltriazatrisilinane, hexaethyltriazatrisilinane, octapropyltriazatrisilinane, octaamethyltriazatrisilinane, octaethyltriazatrisilinane, tetraethyl-tetramethyl-triazatrisilinane, ethyl-pentamethyl-triazatrisilinane, triethyl-triazatrisilinane, trimethyl-triazatrisilinane, tripropyl-triazatrisilinane, and the like.

In one or more embodiments, the precursor consists essentially of one or more of silane, disilane, trisilane, tetrasilane, siloxane, octamethylcyclotetrasiloxane, hexamethylcyclotrisilazane, dimethyldimethoxysilane, vinylmethyldimethoxysilane, trimethyl silane (TMS), tetramethyl silane, methoxy(dimethyl)silylmethane, methyl(dimethoxy)silylmethane, bis(trimethylsilyl)methane, nonamethylcyclotrisilazane, hexaethylcyclotrisilazane, octaethylcyclotrisilazane, 2-ethyl-2,4,4,6,6-pentamethyl-1,3,5,2,4,6-triazatrisilinane, hexapropylcyclotrisilazane, octapropylcyclotrisilazane, Di(butan-2-yl)-fluoro-(2,2,4,4,6,6-hexamethyl-1,3,5,2,4,6-triazatrisilinan-1-yl)silane, Tetraethyl-dimethyl-triazatrisilinane, diethyl-tetramethyl-triazatrisilinane, hexapropyltriazatrisilinane, hexamethyltriazatrisilinane, hexaethyltriazatrisilinane, octapropyltriazatrisilinane, octaamethyltriazatrisilinane, octaethyltriazatrisilinane, tetraethyl-tetramethyl-triazatrisilinane, ethyl-pentamethyl-triazatrisilinane, triethyl-triazatrisilinane, trimethyl-triazatrisilinane, tripropyl-triazatrisilinane, and the like. As used in this manner, the term “consists essentially of” means that the silicon-containing precursor comprises greater than or equal to about 95%, 98%, 99% or 99.5% of one or more of silane, disilane, trisilane, tetrasilane, siloxane, octoamethylcyclotetrasiloxane, hexamethylcyclotrisilazane, dimethyldimethoxysilane, vinylmethyldimethoxysilane, trimethyl silane (TMS), tetramethyl silane, methoxy(dimethyl)silylmethane, methyl(dimethoxy)silylmethane, bis(trimethylsilyl)methane, nonamethylcyclotrisilazane, hexaethylcyclotrisilazane, octaethylcyclotrisilazane, 2-ethyl-2,4,4,6,6-pentamethyl-1,3,5,2,4,6-triazatrisilinane, hexapropylcyclotrisilazane, octapropylcyclotrisilazane, Di(butan-2-yl)-fluoro-(2,2,4,4,6,6-hexamethyl-1,3,5,2,4,6-triazatrisilinan-1-yl)silane, Tetraethyl-dimethyl-triazatrisilinane, diethyl-tetramethyl-triazatrisilinane, hexapropyltriazatrisilinane, hexamethyltriazatrisilinane, hexaethyltriazatrisilinane, octapropyltriazatrisilinane, octaamethyltriazatrisilinane, octaethyltriazatrisilinane, tetraethyl-tetramethyl-triazatrisilinane, ethyl-pentamethyl-triazatrisilinane, triethyl-triazatrisilinane, trimethyl-triazatrisilinane, tripropyl-triazatrisilinane, and the like, on a molecular basis. The presence of diluent, carrier and/or inert gases, for example, is not taken into consideration in the calculation.

In one or more embodiments, the deposition process 15 is carried out at temperatures ranging from about 0° C. to about 500° C., including about 25° C., about 50° C., about 75° C., about 100° C., about 125° C., about 150° C., about 175° C., about 200° C., about 225° C., about 250° C., about 275° C., about 300° C., about 325° C., about 350° C., about 375° C., about 400° C., about 425° C., about 450° C., about 475° C., and about 500° C.

In one or more embodiments, the substrate (or substrate surface) can be any suitable surface. Suitable surfaces include, but are not limited to, silicon (Si), silicon dioxide (SiO₂), silicon oxide (SiOₓ), silicon oxycarbide (SiOC), platinum (Pt), titanium nitride (TiN), tantalum nitride (TaN), copper (Cu), cobalt (Cu), tungsten (W), ruthenium (Ru), molybdenum (Mo), or combinations thereof.

At operation 16, the substrate is exposed to an atmosphere of hydrogen (H₂) gas. Without intending to be bound by theory, it is thought that adding hydrogen (H₂) to the low-k dielectric barrier layer 130 during the PECVD process removes hydrogen-terminate bonds (C—H, N—H, and Si—H) and forms more Si—C—Si bones and Si—N bonds, advantageously increasing the density of the film. In other embodiments, it is thought that adding hydrogen (H₂) to the low-k dielectric barrier layer 130 during the PECVD process breaks both Si—CH₃ bonds and Si—C—Si bonds, forming more Si—N bonds, which advantageously results in higher film density.

In one or more embodiments, the amount of hydrogen (H₂) added is in a range of from greater than 0 sccm to 5000 sccm, including in a range of from greater than 0 sccm to 4500 sccm, or in a range of from greater than 0 sccm to 4000 sccm, or in a range of from greater than 0 sccm to 3500 sccm, or in a range of from greater than 0 sccm to 3000 sccm, or in a range of from greater than 0 sccm to 2500 sccm. In one or more embodiments, the amount of hydrogen (H₂) added to the film is about 25 sccm, or about 50 sccm, or about 75 sccm, or about 100 sccm, or about 125 sccm, or about 150 sccm, 175 sccm, or about 200 sccm, or about 225 sccm, or about 250 sccm, 275 sccm, or about 300 sccm, or about 325 sccm, or about 350 sccm, 375 sccm, or about 400 sccm, or about 425 sccm, or about 450 sccm, 475 sccm, or about 500 sccm, or about 525 sccm, or about 550 sccm, 575 sccm, or about 600 sccm, or about 650 sccm, or about 700 sccm, or about 750 sccm, or about 800 sccm, or about 850 sccm, or about 900 sccm, or about 950 sccm, or about 1000 sccm, or about 1100 sccm, or about 1200 sccm, or about 1300 sccm, or about 1400 sccm, or about 1500 sccm, or about 1600 sccm, or about 1700 sccm, or about 1800 sccm, or about 1900 sccm, or about 2000 sccm, or about 2100 sccm, or about 2200 sccm, or about 2300 sccm, or about 2400 sccm, or about 2500 sccm, or about 2600 sccm, or about 2700 sccm, or about 2800 sccm, or about 2900 sccm, or about 3000 sccm, or about 3100 sccm, or about 3200 sccm, or about 3300 sccm, or about 3400 sccm, or about 3500 sccm, or about 3600 sccm, or about 3700 sccm, or about 3800 sccm, or about 3900 sccm, or about 4000 sccm, or about 4100 sccm, or about 4200 sccm, or about 4300 sccm, or about 4400 sccm, or about 4500 sccm, or about 4600 sccm, or about 4700 sccm, or about 4800 sccm, or about 4900 sccm, or about 5000 sccm.

In one or more embodiments, adding hydrogen (H₂) to the film increases the density of the film such that the density is in a range of from 2.20 g/cm³ to less than 2.50 g/cm³, or in a range of from 2.25 g/cm³ to less than 2.50 g/cm³, or in a range of from 2.26 g/cm³ to less than 2.50 g/cm³, or in a range of from 2.27 g/cm³ to less than 2.50 g/cm³, or in a range of from 2.28 g/cm³ to less than 2.50 g/cm³.

In one or more embodiments, the low-k dielectric barrier layer 130 has a k value in a range of from 4.3 to 4.6.

In some embodiments, operations 16 and 18 are performed simultaneously such that the substrate is exposed to the precursor and the hydrogen (H₂) at the same time. In other embodiments, operations 16 and 18 are performed sequentially such that the substrate is first exposed to the precursor and is then exposed to the hydrogen (H₂).

At operation 20, the substrate (or substrate surface) is exposed to a reactant to form low-k dielectric barrier layer 130 on the substrate. In one or more embodiments, the reactant comprises ammonia (NH₃) or other precursors containing an amino group. In one or more embodiments, the reactant comprises one or more of ammonia (NH₃) or an amino group-containing precursor.

In some embodiments, operations 16 and 18 and 20 are performed simultaneously such that the substrate is exposed to the precursor and the hydrogen (H₂) and the reactant at the same time. In other embodiments, operations 16 and 18 and 20 are performed sequentially such that the substrate is first exposed to the precursor and is then exposed to the hydrogen (H₂) and finally is exposed to the reactant. In yet other embodiments, operations 16 and 18 and 20 are performed sequentially such that the substrate is first exposed to the precursor and is then exposed to the reactant and finally exposed to the hydrogen (H₂).

In one or more embodiments, the low-k dielectric barrier layer 130 comprises silicon oxycarbonitride (SiOCN) or silicon carbonitride (SiCN).

At operation 22, the processing chamber is purged to remove unreacted precursor, unreacted hydrogen (H₂), unreacted reactant, reaction products, and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the rhenium precursor by any suitable technique including, but not limited to, moving the substrate through a gas curtain to a portion or sector of the processing chamber that contains none or substantially none of the rhenium precursor. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur.

In one or more embodiments, the deposition process comprises a remote plasma enhanced chemical vapor deposition process (PECVD). After forming the low-k dielectric barrier layer 130 on the substrate 110, the substrate is exposed to a plasma at operation 24. In one or more embodiments, exposing the low-k dielectric barrier layer to a plasma in the processing chamber improves film properties. For example, in one or more embodiments, the wet etch rate is improved, indicating that the density of the film has been enhanced by plasma treatment. In one or more embodiments, the plasma comprises one or more of nitrogen (N₂), argon (Ar), helium (He), hydrogen (H₂), carbon monoxide (CO), or carbon dioxide (CO₂).

In some embodiments, the plasma is a remote plasma. In other embodiments, the plasma is a direct plasma. In one or more embodiments, the plasma may be generated remotely or within the processing chamber. In one or more embodiments, the plasma is an inductively coupled plasma (ICP) or a conductively coupled plasma (CCP). Any suitable power can be used depending on, for example, the reactants, or the other process conditions. In some embodiments, the plasma is generated with a plasma power in the range of about 10 W to about 3000 W. In some embodiments, the plasma is generated with a plasma power less than or equal to about 3000 W, less than or equal to about 2000 W, less than or equal to about 1000 W, less than or equal to about 500 W, or less than or equal to about 250 W.

At operation 26, the processing chamber is purged after exposure to the plasma. Purging the processing chamber in operation 26 can be the same process or different process than the purge in operation 22. Purging the processing chamber, portion of the processing chamber, area adjacent the substrate surface, etc., removes plasma, reaction products and by-products from the area adjacent the substrate surface.

At decision point 30, in one or more embodiments, the thickness of the deposited film, or number of cycles of precursor, hydrogen (H₂), and reactant is considered. In one or more embodiments, if the deposited film has reached a predetermined thickness or a predetermined number of process cycles have been performed, the method 10 moves to a post-processing operation. In one or more embodiments, if the thickness of the deposited film or the number of process cycles has not reached the predetermined threshold, the method 10 returns to deposition operation 15 to expose the substrate surface to the precursor again in operation 16 and continuing.

In one or more embodiments, the post-processing operation may comprise, for example, a process to modify film properties (e.g., annealing) or a further film deposition process (e.g., additional ALD or CVD processes) to grow additional films. In some embodiments, the post-processing operation may be a process that modifies a property of the deposited film. In some embodiments, the post-processing operation may comprise annealing the as-deposited film. In some embodiments, annealing is performed at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. In one or more embodiments, annealing is performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

The method 10 can be performed at any suitable temperature depending on, for example, the precursor, reactant agent or thermal budget of the device. In some embodiments, exposures to the precursor (operation 16), hydrogen (H₂) (operation 18), and the reactant (operation 20) occur at the same temperature. In some embodiments, the substrate is maintained at a temperature in a range of about 0° C. to about 500° C.

In some embodiments, exposure to the precursor (operation 16) occurs at a different temperature than the exposure to the hydrogen (H₂) (operation 18) or exposure to the reactant (operation 20). In some embodiments, the substrate is maintained at a first temperature in a range of about 100° C. to about 450° C. for the exposure to the precursor, at a second temperature in the range of about 100° C. to 450° C., and at a third temperature in the range of about 100° C. to about 450° C. for exposure the reactant. In such embodiments, three chambers may be needed in the mainframe.

In the embodiment illustrated in FIGS. 1 and 2, at deposition operation 15 the substrate (or substrate surface) is exposed to the precursor, the hydrogen (H₂), and the reactant sequentially. In another embodiment, the substrate (or substrate surface) is exposed to the precursor, the hydrogen (H₂), and the reactant simultaneously in a PE-CVD reaction. In a PE-CVD reaction, the substrate (or substrate surface) is exposed to a gaseous mixture of the precursor, hydrogen (H₂), and reactant to deposit a low-k dielectric barrier layer having a predetermined thickness. In the PE-CVD reaction, a low-k dielectric barrier layer can be deposited in one exposure to the mixed reactive gas or can be multiple exposures to the mixed reactive gas with purges between.

In one or more embodiments, the deposition process is carried out in a process volume at pressures ranging from 0.1 mTorr to 10 Torr, including a pressure of about 0.1 mTorr, about 1 mTorr, about 10 mTorr, about 100 mTorr, about 500 mTorr, about 1 Torr, about 2 Torr, about 3 Torr, about 4 Torr, about 5 Torr, about 6 Torr, about 7 Torr, about 8 Torr, about 9 Torr, and about 10 Torr.

The precursor-containing gas mixture may further include one or more of a dilution gas selected from helium (He), argon (Ar), xenon (Xe), nitrogen (N₂), or hydrogen (H₂). The dilution gas of some embodiments comprises a compound that is inert gas relative to the reactants and substrate materials.

The plasma (e.g., capacitive-coupled plasma) may be formed from either top and bottom electrodes or side electrodes. The electrodes may be formed from a single powered electrode, dual powered electrodes, or more electrodes with multiple frequencies such as, but not limited to, 350 KHz, 2 MHz, 13.56 MHz, 27 MHz, 40 MHz, 60 MHz and 100 MHz, being used alternatively or simultaneously in a CVD system with any or all of the reactant gases listed herein to deposit a thin film of dielectric. In some embodiments, the plasma is a capacitively coupled plasma (CCP). In some embodiments, the plasma is an inductively coupled plasma (ICP). In some embodiments, the plasma is a microwave plasma.

According to one or more embodiments, the substrate is subjected to processing prior to and/or after forming the barrier layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

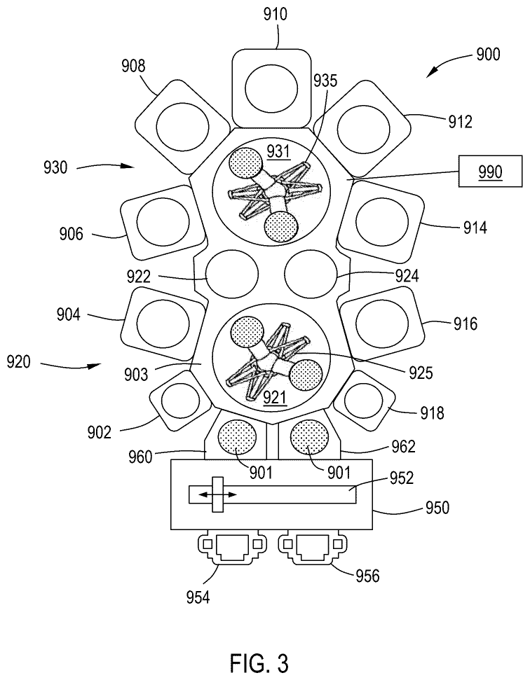

Additional embodiments of the disclosure are directed to processing tools for the methods described herein, as shown in FIG. 3. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station 921, 931. The various processing chambers provide separate processing regions isolated from adjacent process chambers. The processing chambers can be any suitable chamber including, but not limited to, a pre-clean chamber, a buffer chamber, transfer space(s), a wafer orienter/degas chamber, a cryo cooling chamber, a deposition chamber, an annealing chamber, an etching chamber, a thermal processing (RTP) chamber, a plasma treatment chamber, and an atomic layer deposition (ALD) chamber. The particular arrangement of process chambers and components can be varied depending on the cluster tool and should not be taken as limiting the scope of the disclosure.

In one or more embodiments, the cluster tool 900 includes a deposition chamber to deposit the doped dielectric layer 230. The deposition chamber of some embodiments comprises a PECVD deposition chamber. In one or more embodiments, the cluster tool 900 includes a soak chamber connected to the central transfer station.

In the embodiment shown in FIG. 3, a factory interface 950 is connected to the front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware such as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A silicon oxycarbonitride film was deposited on a substrate. Dimethyldimethoxysilane (DMDMOS) was flowed into a reaction chamber in a carrier gas of helium (g), followed by flowing a stream of ammonia (NH₃) over the substrate and turning on the bias power at about 3000 W to generate a plasma. The substrate was then treated with an ammonia plasma in an atmosphere of Ar(g) at a pressure of about 0.7 T for about 15 seconds. A silicon oxycarbonitride film was deposited on the substrate. A flow of argon (Ar) was then passed over the substrate for 30 seconds. The substrate was annealed at 400° C., at a pressure of 5 T, in an atmosphere of nitrogen (N₂) for 10 minutes.

### Example 2

A silicon oxycarbonitride film was deposited on a substrate. Dimethyldimethoxysilane (DMDMOS) and 500 sccm hydrogen (H₂) were coflowed into a reaction chamber in a carrier gas of helium (g), followed by flowing a stream of ammonia (NH₃) over the substrate and turning on the bias power at about 3000 W to generate a plasma. The substrate was then treated with an ammonia plasma in an atmosphere of Ar(g) at a pressure of about 0.7 T for about 15 seconds. A silicon oxycarbonitride film was deposited on the substrate. A flow of argon (Ar) was then passed over the substrate for 30 seconds. The substrate was annealed at 400° C., at a pressure of 5 T, in an atmosphere of nitrogen (N₂) for 10 minutes.

### Example 3

A silicon oxycarbonitride film was deposited on a substrate. Dimethyldimethoxysilane (DMDMOS) and 1500 sccm hydrogen (H₂) were coflowed into a reaction chamber in a carrier gas of helium (g), followed by flowing a stream of ammonia (NH₃) over the substrate and turning on the bias power at about 3000 W to generate a plasma. The substrate was then treated with an ammonia plasma in an atmosphere of Ar(g) at a pressure of about 0.7 T for about 15 seconds. A silicon oxycarbonitride film was deposited on the substrate. A flow of argon (Ar) was then passed over the substrate for 30 seconds. The substrate was annealed at 400° C., at a pressure of 5 T, in an atmosphere of nitrogen (N₂) for 10 minutes.

### Example 4

A silicon oxycarbonitride film was deposited on a substrate. Dimethyldimethoxysilane (DMDMOS) and 2500 sccm hydrogen (H₂) were coflowed into a reaction chamber in a carrier gas of helium (g), followed by flowing a stream of ammonia (NH₃) over the substrate and turning on the bias power at about 3000 W to generate a plasma. The substrate was then treated with an ammonia plasma in an atmosphere of Ar(g) at a pressure of about 0.7 T for about 15 seconds. A silicon oxycarbonitride film was deposited on the substrate. A flow of argon (Ar) was then passed over the substrate for 30 seconds. The substrate was annealed at 400° C., at a pressure of 5 T, in an atmosphere of nitrogen (N₂) for 10 minutes.

Tables 1 and 2 show the characterization of the films.

TABLE 1

| Film | k value | Density (g/cm³) |
|---|---|---|
| Comparative Example 1 | 4.32 | 2.28 |
| Example 2 | 4.40 | 2.33 |
| Example 3 | 4.48 | 2.38 |

TABLE 2

| | | | | | | Si—O/ |
|---|---|---|---|---|---|---|
| | | | | | | Si—C/ |
| Film | N—H | C—H | Si—H | Si—C—Si | Si—CH₃ | Si—N |
| Example 1 | 8.81 | 2.15 | 35.1 | 18.1 | 3.6 | 419.7 |
| Example 2 | 8.03 | 2.14 | 33.0 | 21.2 | 2.6 | 433.8 |
| Example 3 | 8.07 | 2.03 | 30.7 | 19.9 | 1.8 | 445.8 |

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

1. A method of depositing a film, the method comprising:
forming a barrier layer on a substrate surface by exposing the substrate surface to hydrogen (H₂) and a silicon-containing precursor;
exposing the substrate to a reactant to react with the silicon-containing precursor to form one or more of a silicon carbonitride (SiCN) film or a silicon oxycarbonitride (SiOCN) film on the substrate; and
exposing the substrate surface to a plasma.

2. The method of claim 1, wherein the silicon-containing precursor has a structure of general formula (I) or general formula (II) or a general formula (III) or a general formula (IV) 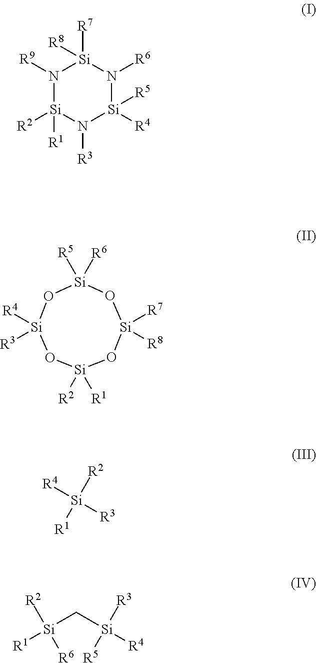
wherein R¹, R², R³, R⁴, R⁵, R⁶, R⁷, R⁸, and R⁹, are independently selected from hydrogen (H), substituted or unsubstituted alkyl, substituted or unsubstituted alkoxy, substituted or unsubstituted vinyl, silane, substituted or unsubstituted amine, or halide.

3. The method of claim 1, wherein the hydrogen (H₂) is present in an amount in a range of from greater than 0 sccm to 5000 sccm.

4. The method of claim 1, wherein the plasma is a remote plasma.

5. The method of claim 1, wherein the plasma comprises one or more of ammonia (NH₃), nitrogen (N₂), argon (Ar), helium (He), hydrogen (H₂), carbon monoxide (CO), or carbon dioxide (CO₂).

6. The method of claim 1, wherein the substrate surface is exposed to the precursor and hydrogen (H₂) simultaneously.

7. The method of claim 1, wherein the substrate surface is exposed to the precursor and the hydrogen (H₂) sequentially.

8. The method of claim 1, wherein the barrier layer has a thickness in a range of about 50 Å to about 1000 Å.

9. The method of claim 1, wherein the barrier layer is formed at a temperature in a range of from about 100° C. to about 450° C.

10. The method of claim 1, wherein the barrier layer is one or more of a silicon carbonitride (SiCN) film or a silicon oxycarbonitride (SiOCN) film.

11. The method of claim 1, wherein the silicon-containing precursor comprises one or more of silane, disilane, trisilane, tetrasilane, siloxane, octoamethylcyclotetrasiloxane, hexamethylcyclotrisilazane, dimethyldimethoxysilane, vinylmethyldimethoxysilane, trimethyl silane (TMS), tetramethyl silane, methoxy(dimethyl)silylmethane, methyl(dimethoxy)silylmethane, bis(trimethylsilyl)methane, nonamethylcyclotrisilazane, hexaethylcyclotrisilazane, octaethylcyclotrisilazane, 2-ethyl-2,4,4,6,6-pentamethyl-1,3,5,2,4,6-triazatrisilinane, hexapropylcyclotrisilazane, octapropylcyclotrisilazane, Di(butan-2-yl)-fluoro-(2,2,4,4,6,6-hexamethyl-1,3,5,2,4,6-triazatrisilinan-1-yl)silane, Tetraethyl-dimethyl-triazatrisilinane, diethyl-tetramethyl-triazatrisilinane, hexapropyltriazatrisilinane, hexamethyltriazatrisilinane, hexaethyltriazatrisilinane, octapropyltriazatrisilinane, octaamethyltriazatrisilinane, octaethyltriazatrisilinane, tetraethyl-tetramethyl-triazatrisilinane, ethyl-pentamethyl-triazatrisilinane, triethyl-triazatrisilinane, trimethyl-triazatrisilinane, tripropyl-triazatrisilinane, and the like.

12. The method of claim 1, wherein the reactant comprises one or more of ammonia (NH₃) or an amino group-containing precursor.

13. The method of claim 1, further comprising purging the substrate surface of the precursor, hydrogen (H₂), and the reactant.

14. The method of claim 13, wherein purging the substrate surface comprises flowing a purge gas over the substrate.

15. The method of claim 14, wherein the purge gas is selected from one or more of argon (Ar), nitrogen (N₂), and helium (He).

16. A non-transitory computer readable medium including instructions, that, when executed by a controller of a processing chamber, causes the processing chamber to perform operations of:
expose a substrate surface to hydrogen (H₂) and a silicon-containing precursor having a structure of general formula (I) or general formula (II) or a general formula (III) or a general formula (IV) 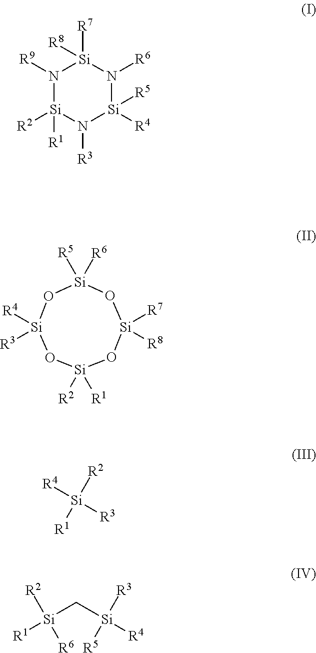
wherein R¹, R², R³, R⁴, R⁵, R⁶, R⁷, R⁸, and R⁹, are independently selected from hydrogen (H), substituted or unsubstituted alkyl, substituted or unsubstituted alkoxy, substituted or unsubstituted vinyl, silane, substituted or unsubstituted amine, or halide;
expose the substrate to a reactant to react with the silicon-containing precursor to form one or more of a silicon carbonitride (SiCN) film or a silicon oxycarbonitride (SiOCN) film on the substrate; and
expose the substrate surface to a plasma.

17. The non-transitory computer readable medium of claim 16, wherein the hydrogen (H₂) is present in an amount in a range of from greater than 0 sccm to 5000 sccm.

18. The non-transitory computer readable medium of claim 16, wherein the plasma comprises one or more of ammonia (NH₃), nitrogen (N₂), argon (Ar), helium (He), hydrogen (H₂), carbon monoxide (CO), or carbon dioxide (CO₂).

19. The non-transitory computer readable medium of claim 16, wherein the substrate surface is exposed to the precursor and hydrogen (H₂) simultaneously.

20. The non-transitory computer readable medium of claim 16, wherein the substrate surface is exposed to the precursor and the hydrogen (H₂) sequentially.
